(19) United States
(12) Patent Application Publication
(10) Pub. No.: US 2025/0183185 A1
(43) Pub. Date: Jun. 5, 2025

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Hsin-Yin CHANG, Taichung City (TW); Yi-Wen LIU, Taichung City (TW); Hsiu-Jung LI, Taichung City (TW); Wan-Rpu CHEN, Taichung City (TW); Chih-Chieh SUN, Taichung City (TW); Kai-Lun LIANG, Taichung City (TW)

(21) Appl. No.: 18/747,278

(22) Filed: Jun. 18, 2024

(30) Foreign Application Priority Data
Dec. 5, 2023 (TW) 112147251

(51) Int. Cl. H01L 23/538; H01L 21/48; H01L 23/00; H01L 23/498; H01L 25/16

(52) U.S. Cl. CPC H01L 23/5386; H01L 21/4857; H01L 23/49822; H01L 23/49838; H01L 24/16; H01L 25/16; H01L 2224/16225; H01L 2924/19105

(57) ABSTRACT

An electronic package and manufacturing method are provided. The electronic package includes a carrier structure and an electronic element. The carrier structure has a first side and a second side opposing the first side and includes at least one insulation layer and at least one circuit layer bonded to the at least one insulation layer. The electronic element is disposed on the first side of the carrier structure. A portion of each of the circuit layers of the carrier structure in a response region below the electronic element is hollowed out to reduce signal interference during high frequency signal transmission and to enhance the reliability of high frequency transmission.

### CROSS-REFERENCE TO RELATED APPLICATIONS

The present application is based upon and claims the right of priority to TW patent application No. 112147251, filed Dec. 5, 2023, the disclosure of which is hereby incorporated by reference herein in its entirety for all purposes.

### BACKGROUND

### 1. Technical Field

The present disclosure relates to a semiconductor packaging process, and more particularly, to an electronic package and manufacturing method thereof.

### 2. Description of Related Art

FIG. 1 is a schematic cross-sectional view of a semiconductor package 1 with a conventional flip chip structure. The semiconductor package 1 comprises a semiconductor chip 16, a plurality of solder bumps 17, a package substrate 10, and a plurality of solder balls 18. The semiconductor chip 16 is bonded to the package substrate 10 by solder bumps 17. The solder balls 18 are disposed beneath the package substrate 10. The package substrate 10 comprises solder mask layers 131, 132, insulation layers 111, 112 disposed between the solder mask layers 131, 132, circuit layers 121-123 bonded to the insulation layers 111, 112, and conductive vias 141, 142 are electrically connected to the circuit layers 121-123.

Conventional high frequency signal transmission path is connected to solder balls from solder bumps through circuit layers and conductive vias in series, for instance, a high frequency signal transmission path 15 as shown in FIG. 1 is connected to the solder ball 18 from the solder bump 17 through the circuit layers 121-123 and the conductive vias 141˜142 in series; however, this transmission path is likely to cause greater signal interference.

Therefore, there is a need for a solution that addresses the aforementioned shortcomings in the prior art.

### SUMMARY

In view of the aforementioned shortcomings of the prior art, the present disclosure provides an electronic package, which comprises: a carrier structure having a first side and a second side opposing the first side and including at least one insulation layer and at least one circuit layer bonded to the at least one insulation layer, and an electronic element disposed on the first side of the carrier structure, wherein a portion of the circuit layer of the carrier structure in a response region beneath the electronic element is hollowed out.

The present disclosure further provides a method of manufacturing an electronic package, which comprises: forming a carrier structure, wherein the carrier structure having a first side and a second side opposing the first side and including at least one insulation layer and at least one circuit layer bonded to the at least one insulation layer; and disposing an electronic element on the first side of the carrier structure, wherein a portion of the circuit layer of the carrier structure in a response region beneath the electronic element is hollowed out.

In the present disclosure, the circuit layer is hollowed out in the response region beneath the electronic element to reduce signal interference during high frequency signal transmission and enhance the reliability of high frequency transmission to solve conventional technical problems that it is likely to cause greater signal interference since high frequency signal transmission is connected to solder ball end on a lower side of the package substrate merely through circuit and vias in the package substrate in series.

### BRIEF DESCRIPTION OF THE DRAWINGS

FIG. 1 is a schematic cross-sectional view of a conventional semiconductor package.

FIG. 2 to FIG. 4 are schematic cross-sectional views of an electronic package of the present disclosure at each stage in a manufacturing method thereof.

FIG. 5 to FIG. 7 are schematic partial cross-sectional views of a carrier structure of an electronic package of the present disclosure.

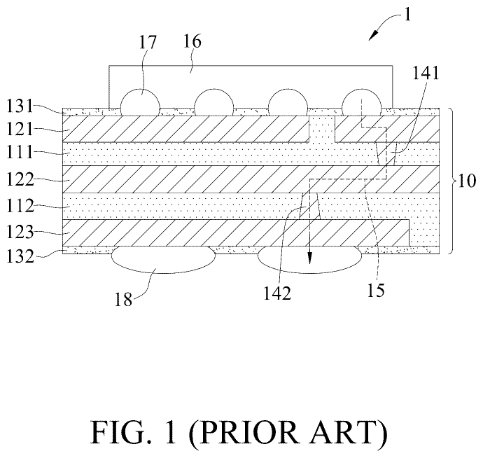

### DETAILED DESCRIPTION

The following describes the implementation of the present disclosure with examples. Those skilled in the art can easily understand other advantages and effects of the present disclosure from the contents disclosed in this specification.

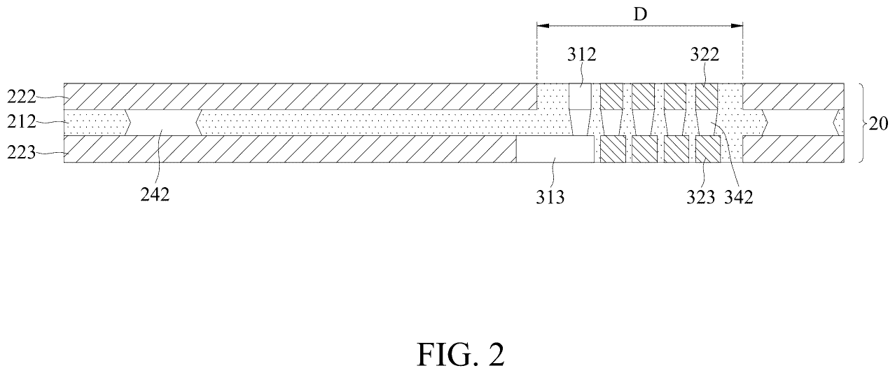

FIG. 2 to FIG. 4 are schematic cross-sectional views of an electronic package 2 of the present disclosure at each stage in a manufacturing method thereof. In the manufacturing method, firstly as shown in FIG. 2, an insulation layer 212, circuit layers 222, 223, and other structures arranged on the same layer as the aforementioned circuit layers and insulation layer of a carrier structure 20 are formed. In an embodiment, the insulation layer 212 and the circuit layers 222, 223 are formed as for example copper foil substrates, and a response region D is defined in the carrier structure 20, which mainly removes the copper foil substrate corresponding to the copper foil part of the response region D. In addition, in this embodiment, a conductive via 242 electrically connected to the circuit layers 222, 223 is formed in the insulation layer 212 outside the response region D, conductive circuits 312, 313, 322, 323 and a conductive via 342 electrically connected to the conductive circuits 312, 313, 322, 323 are formed in the insulation layer 212 inside the response region D.

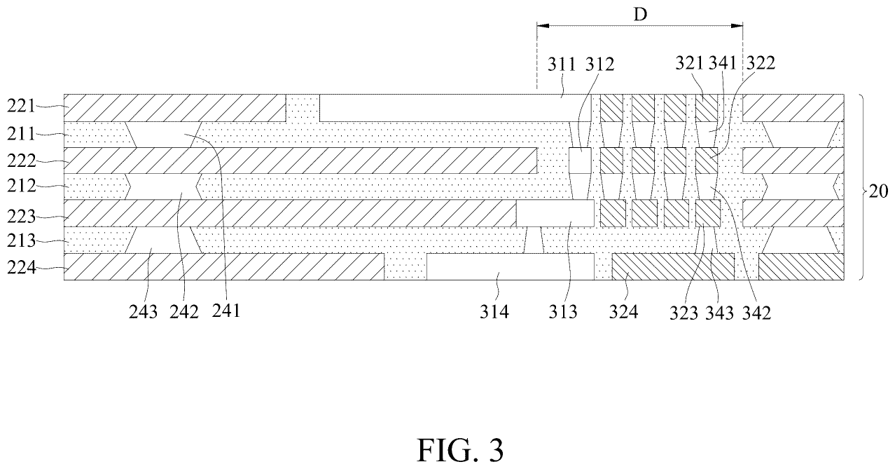

As shown in FIG. 3, insulation layers 211, 213, circuit layers 221, 224, and other structures arranged on the same layer as the aforementioned circuit layers and insulation layers of a carrier structure 20 are formed. In this embodiment, the insulation layers 211, 213 and circuit layers 221, 224 are formed as for example copper foil substrates, and the copper foil part of the copper foil substrate inside the response region D are also removed. In addition, in this embodiment, conductive vias 241, 243 are formed in the insulation layers 211, 213 outside the response region D, conductive circuits 311, 314, 321, 324 and conductive vias 341, 343 are formed in the insulation layers 211, 213 inside the response region D.

Materials for forming insulation layers 211-213 are polybenzoxazole (PBO), polyimide (PI), prepreg (PP), or other dielectric materials. Materials for forming circuit layers 221-224, conductive circuits 311-314, 321-324, and conductive vias 241-243, 341-343 are copper.

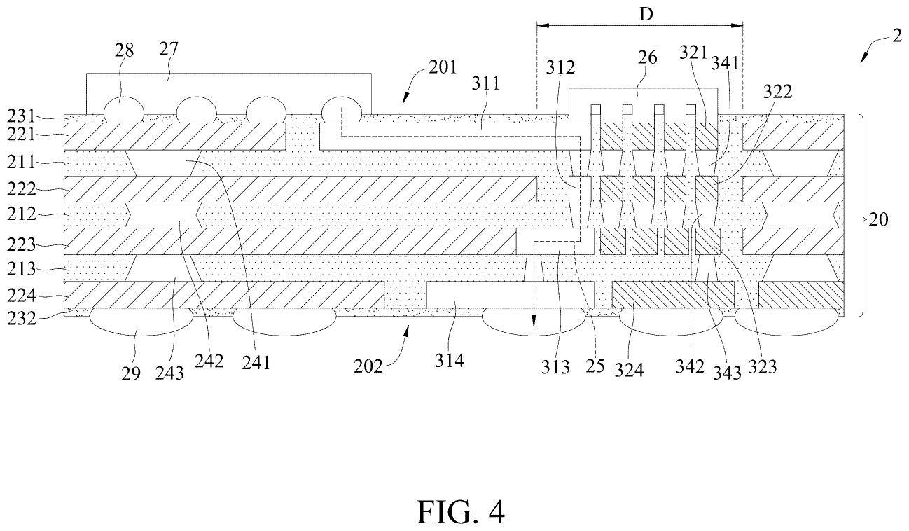

As shown in FIG. 4, a solder mask layer 231 is formed on the first side 201 of the carrier structure 20, and a solder mask layer 232 is formed on the second side 202 opposing the first side 201 of the carrier structure 20. The solder mask layers 231, 232 can be green paint, graphite, or other solder masks.

In addition, a plurality of openings are formed in the solder mask layer 231 to dispose the first electronic element 26 in the response region D on the first side 201 of the carrier structure 20 through a part of the plurality of openings, and to dispose the second electronic element 27 in a non-response region on the first side 201 of the carrier structure 20 by a plurality of conductive bumps 28 through another part of the plurality of openings.

In an embodiment, the first electronic element 26 is an integrated passive device (IPD). The integrated passive device has excellent characteristics of small element dimension, thin profile, low loss of high frequency dielectric, high thermal conductivity, low thermal expansion coefficient, better equivalent series impedance and inductance performance at high frequencies, stable voltage, high reliability, and easy for package and assembly.

Conductive bumps 28 can be solder bumps, copper bumps, or other materials.

The second electronic element 27 is an active element, a passive element, or a combination of them, and the active element may be a semiconductor chip, and the passive element may be a resistor, a capacitor, and/or an inductor.

In an embodiment, the second electronic element 27 is an active element electrically connected to the circuit structure in the carrier structure 20 by a plurality of conductive bumps 28 in a flip-chip manner. Alternatively, the second electronic element 27 can be electrically connected to the circuit structure in the carrier structure 20 by a plurality of wires (not shown) in a wire bonding manner, and the second electronic element 27 can also in direct contact to the circuit structure in the carrier structure 20.

In addition, a plurality of openings are formed on the solder mask layer 232 to dispose a plurality of conductive elements 29 on the second side 202 of the carrier structure 20 through the plurality of openings. The conductive element 29 can be a metal pillar such as a copper pillar, a metal bump covering with an insulator block, a solder ball, or a solder ball with a core copper ball, etc.

As shown in FIG. 4, the electronic package 2 of the present disclosure comprises a first electronic element 26, a second electronic element 27, a plurality of conductive bumps 28, a plurality of conductive elements 29, and a carrier structure 20.

The carrier structure 20 can be a package substrate with a coreless circuit structure.

The carrier structure 20 can comprises at least one insulation layer and at least one circuit layer bonded to the at least one insulation layer. In an embodiment, the carrier structure 20 comprises insulation layers 211-213 and circuit layers 221-224. Furthermore, the carrier structure 20 further comprises solder mask layers 231, 232, conductive vias 241-243, 341-343, and conductive circuits 311-314, 321-324.

The circuit layer 221 is electrically connected to the second electronic element 27 through the conductive bumps 28. The conductive circuit 311 is electrically connected to the second electronic element 27 through the conductive bumps 28, and electrically connected to the first electronic element 26. The conductive circuit 321 is electrically connected to the first electronic element 26.

The circuit layer 222 is electrically connected to the circuit layer 221 through the conductive via 241. The conductive circuit 312 is electrically connected to the circuit layer 311 through the conductive via 341. The conductive circuit 322 is electrically connected to the circuit layer 321 through the conductive via 341.

The circuit layer 223 is electrically connected to the circuit layer 222 through the conductive via 242. The conductive circuit 313 is electrically connected to the circuit layer 312 through the conductive via 342. The conductive circuit 323 is electrically connected to the circuit layer 322 through the conductive via 342.

The circuit layer 224 is electrically connected to the circuit layer 223 through the conductive via 243, and electrically connected to the conductive element 29. The conductive circuit 314 is electrically connected to the circuit layer 313 through the conductive via 343, and electrically connected to the conductive element 29. The conductive circuit 324 is electrically connected to the circuit layer 323 through the conductive via 343, and electrically connected to the conductive element 29.

The circuit layers 221-224 and the conductive circuits 311-314, 321-324 constitute the circuit structure of the carrier structure 20. The circuit structure is divided into four layers embedded in the insulation layers 211-213. The first layer of the circuit structure comprises the circuit layer 221, the conductive circuit 311 and the conductive circuit 321. The second layer of the circuit structure comprises the circuit layer 222, the conductive circuit 312 and the conductive circuit 322. The third layer of the circuit structure comprises the circuit layer 223, the conductive circuit 313 and the conductive circuit 323. The fourth layer of the circuit structure comprises the circuit layer 224, the conductive circuit 314 and the conductive circuit 324. The conductive vias 241-243, 341-343 are disposed between each layer of the circuit structure for electrically connecting to each layer of the circuit structure. The circuit structure of the present disclosure is for instance a four-layer structure, but can be other layer structures in other embodiments, and not limited to this embodiment.

The carrier structure 20 further comprises a transmission path 25. The transmission path 25 can comprises at least one conductive circuit and at least one conductive via electrically connected to each the conductive circuit. As shown in FIG. 4, the transmission path 25 comprises the conductive circuits 311-314 and the conductive vias 341-343 electrically connected to the conductive circuits 311-314, wherein the conductive circuit 311 electrically connected to the conductive bump 28, and the conductive circuit 314 electrically connected to the conductive component 29.

Through the conductive circuits 311-314 and the conductive vias 341-343, the transmission path 25 is electrically connected to the first electronic element 26 and the second electronic element 27 and electrically connected to the conductive bump 28 disposed on the first side 201 of the carrier structure 20 and to the conductive element 29 disposed on the second side 202 of the carrier structure 20. Therefore, the transmission path 25 can be used to transmit high frequency signal output by the second electronic element 27 from the conductive bump 28 on the first side 201 of the carrier structure 20 to the conductive element 29 on the second side 202 through the first electronic element 26. In other words, the transmission path 25 connects the conductive bump 28 on the first side 201 of the carrier structure 20 and the conductive element 29 on the second side 202 in series by the first electronic element 26. In addition, the aforementioned high frequency signal refers to electrical signal with a frequency from 4.8 GHz to 7.2 GHz.

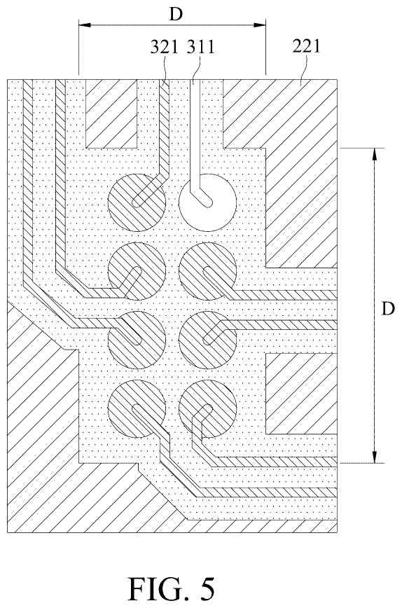

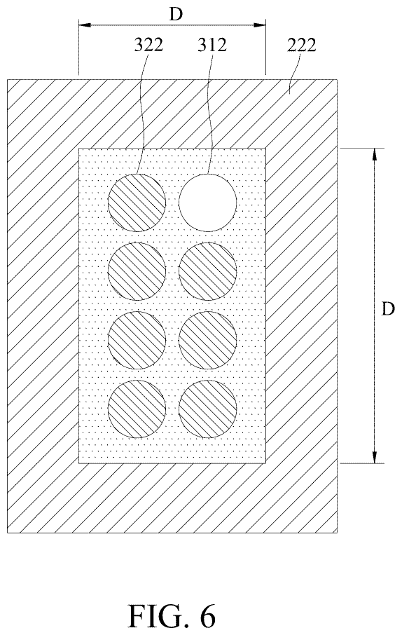

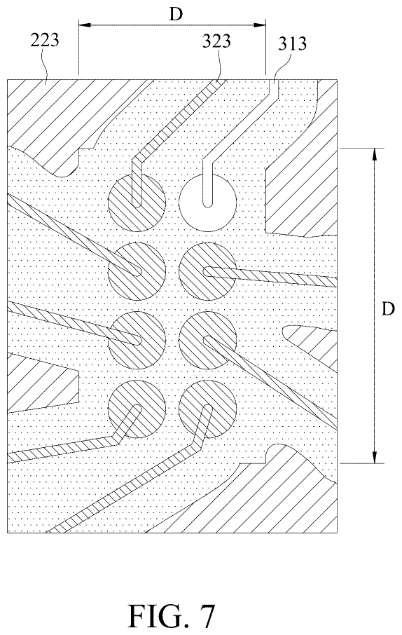

Please refers to FIG. 4 to FIG. 7 at the same time, FIG. 5 to FIG. 7 are schematic top views respectively showing the first layer, the second layer, the third layer of the circuit structure in the carrier structure 20 of the electronic package 2 located on a part in the response region D beneath the first electronic element 26. In the carrier structure 20, the part of the circuit layers 221-224 (cooper foil portion) in the response region D beneath the first electronic element 26 is hollowed out, and the conductive circuits 311-314, the conductive circuits 321-324, and a plurality of conductive vias 341-343 are formed in the response region D and adjacent region thereof.

It can be seen in FIG. 4 to FIG. 7, the transmission path 25 is (comprising the conductive circuits 311-314 and the conductive vias 341˜343 electrically connected to the conductive circuits 311-314, wherein the conductive circuit 311 is electrically connected to the conductive bump 28, and the conductive circuit 314 is electrically connected to the conductive element 29) at least partially passed through the response region D in the carrier structure 20. As such, the hollowed out circuit layers 221-224 in the response region D can reduce signal interference during high frequency signal transmission.

In the present disclosure, the first electronic element 26 is connected to the conductive bumps on the first side of the carrier structure 20 and to the conductive element end on the second side of the carrier structure 20 in series, such that the filter function can be achieved when the signal entering and the voltage can be stabilized to reduce damages to the electronic elements. In addition, the present disclosure hollows out the circuit layers 221-224 in the response region D beneath the first electronic element 26 to reduce signal interference when high frequency transmission and to enhance the reliability of high frequency transmission to solve conventional technical problems that it is likely to cause greater signal interference since high frequency signal transmission is connected to solder ball end on the lower side of the package substrate merely through the circuit and the vias in the package substrate in series.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An electronic package, comprising:
a carrier structure having a first side and a second side opposing the first side, and including an insulation layer and a circuit layer bonded to the insulation layer, and defined with a response region, wherein a portion of the circuit layer in the response region is hollowed out; and
a first electronic element disposed on the first side of the carrier structure and in the response region.

2. The electronic package of claim 1, wherein the first electronic element is an integrated passive device.

3. The electronic package of claim 1, further comprising:
a second electronic element disposed on the first side of the carrier structure, and outside the response region; and
a transmission path electrically connected to the first electronic element and the second electronic element and electrically connected to the first side and the second side of the carrier structure for transmitting the high frequency signal output by the second electronic element from the first side to the second side of the carrier structure through the first electronic element.

4. The electronic package of claim 3, wherein the transmission path comprises conductive circuits.

5. The electronic package of claim 4, wherein the transmission path further comprises conductive vias electrically connected to the conductive circuits.

6. The electronic package of claim 3, wherein the transmission path passes through the response region of the carrier structure.

7. The electronic package of claim 3, further comprising:
a plurality of conductive bumps disposed on the first side of the carrier structure, and electrically connected to the second electronic element and the transmission path.

8. The electronic package of claim 3, further comprising:
a plurality of conductive elements disposed on the second side of the carrier structure and electrically connected to the transmission path.

9. A method of manufacturing an electronic package, comprising:
providing a carrier structure having a first side and a second side opposing the first side, and including an insulation layer and a circuit layer bonded to the insulation layer, wherein a portion of the circuit layer in a response region is hollowed out; and
disposing a first electronic element on the first side of the carrier structure and in the response region.

10. The method of claim 9, wherein the first electronic element is an integrated passive device.

11. The method of claim 9, further comprising:
disposing a second electronic element on the first side of the carrier structure, wherein the carrier structure further comprising a transmission path electrically connected to the first electronic element and the second electronic element, and electrically connected to the first side and the second side of the carrier structure, a high frequency signal output by the second electronic element is transmit by the transmission path from the first side to the second side of the carrier structure through the first electronic element.

12. The method of claim 11, wherein the transmission path comprises conductive circuits.

13. The method of claim 12, wherein the transmission path further comprises conductive vias electrically connected to the conductive circuits.

14. The method of claim 11, wherein the transmission path is passed through the response region of the carrier structure.

15. The method of claim 11, further comprising:
disposing a plurality of conductive bumps on the first side of the carrier structure, wherein the plurality of conductive bumps are electrically connected to the second electronic element and the transmission path.

16. The method of claim 11, further comprising:
disposing a plurality of conductive elements on the second side of the carrier structure, wherein the plurality of conductive components are electrically connected to the transmission path.
